(19) United States
(12) Patent Application Publication
(10) Pub. No.: US 2022/0036168 A1
(43) Pub. Date: Feb. 3, 2022

(54) ION CONTROLLABLE TRANSISTOR FOR NEUROMORPHIC SYNAPSE DEVICE AND MANUFACTURING METHOD THEREOF

(71) Applicant: KOREA ADVANCED INSTITUTE OF SCIENCE AND TECHNOLOGY, Daejeon (KR)

(72) Inventors: Yang-Kyu CHOI, Daejeon (KR); Ji-Man YU, Daejeon (KR)

(21) Appl. No.: 17/385,329

(22) Filed: Jul. 26, 2021

(30) Foreign Application Priority Data
Jul. 29, 2020 (KR) 10-2020-0094128
Dec. 17, 2020 (KR) 10-2020-0177102

(51) Int. Cl. G06N 3/063; H01L 29/49; H01L 29/78; H01L 21/265; H01L 29/66; H01L 27/088

(52) U.S. Cl. CPC G06N 3/063; H01L 29/49; H01L 27/088; H01L 21/265; H01L 29/66545; H01L 29/78

(57) ABSTRACT

Disclosed is an ion controllable transistor-based neuromorphic synaptic device used for a memory and a neuromorphic computing in such a manner that a synaptic weight is analogically updated and maintained. The ion controllable transistor-based neuromorphic synaptic device includes a channel area formed on a semiconductor substrate; a source area and a drain area formed at both sides of the channel area, respectively; an interlayer insulating film provided on the channel area; a gate area formed on the interlayer insulating film; and a solid electrolyte layer inserted between the interlayer insulating film and the gate area.

### CROSS-REFERENCE TO RELATED APPLICATION

This application claims the priority benefit of Korean Patent Application No. 10-2020-0094128, filed on Jul. 29, 2020, in the Korean Intellectual Property Office, the disclosure of which is incorporated herein by reference.

### BACKGROUND

### 1. Field of the Invention

The following example embodiments relate to an ion controllable transistor-based neuromorphic synaptic device and a manufacturing method thereof and, more particularly, to technology for a neuromorphic synaptic device used as a system that implements a memory and a neuromorphic computing.

### 2. Description of the Related Art

With the advent of a bigdata era, a demand for computing, processing, and storing a vast amount of data is explosively increasing. A von Neumann structure used in an existing computer system is a structure in which a central processing unit (CPU) that processes and computes data and a memory that stores the processed and computed data are separated. In a data exchange process between the CPU and the memory according to an increase in an amount of data in the bigdata era, the bottleneck and energy consumption are issues that should be solved.

As a solution to issues found in the existing computer system, there is a movement to implement a system that mimics the human brain, which is called a neuromorphic computing. Dissimilar to the existing von Neumann computing, a deep neural network in the neuromorphic computing requires a synapse with a specific synaptic weight connected in parallel and a neuron that passes the same to a subsequent synapse and, when performs an operation based thereon, may perform accurate and fast learning and inference with efficient energy consumption.

Many studies on the deep neural network have been conducted in a way of processing data using software. However, to implement a true ultra-low-power neuromorphic computing, suitable hardware is indispensably required and it is essential to secure synaptic and neuron devices that enable a parallel operation and have energy efficiency from a device stage.

For an ideal synaptic device to implement the deep neural network, there is a need for an analog synaptic weight update characteristic in which a channel conductance value varies as the same pulse voltage is applied, a characteristic in which a synaptic weight update is linearly potentiated and depressed based on a number of pulses, a non-volatile characteristic in which an updated synaptic weight is stored regardless of power supply, and excellent endurance in which a characteristic does not change even after the synaptic weight update is performed several times.

Devices, such as a 2-terminal-based resistive random access memory (RRAM), phase-change random access memory (PCRAM), and memristor, have a principle of changing an analog weight like a human nervous system by changing and memorizing a resistance of a channel itself through which current flows as a voltage pulse is applied and receive great attention as synaptic devices in that the devices may operate with low power and enable integration.

However, since a variable resistance characteristic of a channel through which current flows rapidly changes due to a device characteristic, the devices have a low linearity for a weight change and a poor endurance. Also, in the case of a 2-terminal-based synaptic device, an additional selector device and circuit elements may be required when manufacturing the 2-terminal based synaptic device in an array form for the overall system configuration.

As a solution to the above issues, research on a transistor-based synaptic device is currently actively conducted. In the case of the transistor-based synaptic device, parallel write and read operations are possible and an additional selector device is not required. Here, similar to a neurotransmission system of a real living organism, an ion controllable transistor may perform a channel conductance and analog synaptic weight update through ion-based potential adjustment and may also perform a linear synaptic weight update through movement of ions in an electrolyte in an analog manner.

However, the existing ion controllable transistor has been manufactured using an electrolyte in a liquid or ion gel type, which may be unstable for manufacturing a synaptic device that essentially requires a large-scale process and integration. Also, in the case of the electrolyte in the liquid or ion gel type, it is difficult to secure a stable device characteristic over time.

### SUMMARY

Example embodiments provide a neuromorphic synaptic device that may secure a stable device characteristic and, at the same time, achieve a large-scale process and integration by using a solid electrolyte layer that analogically updates a channel conductance and a synaptic weight by movement of ions present in the solid electrolyte layer.

In detail, example embodiments provide a neuromorphic synaptic device that may implement a memory operation through a linear movement of cations and anions present in a solid electrolyte layer and may memorize a change in channel conductance caused by ion movement as a synaptic weight.

Also, example embodiments provide a neuromorphic synaptic device that may implement spike timing dependent plasticity (STDP), short term plasticity (STP), and long term plasticity (LTP) characteristics like a synapse of a real living organism by adjusting a frequency ad a width of a voltage pulse applied to a gate area or by adjusting materials that form a channel area, a solid electrolyte area, the gate area, and a source area.

According to an aspect of an example embodiment, there is provided an ion controllable transistor-based neuromorphic synaptic device including a channel area formed on a semiconductor substrate; a source area and a drain area formed at both sides of the channel area, respectively; an interlayer insulating film provided on the channel area; a gate area formed on the interlayer insulating film; and a solid electrolyte layer inserted between the interlayer insulating film and the gate area.

In response to a voltage pulse being applied to the gate area, the ion controllable transistor-based neuromorphic synaptic device may analogically update channel conductance by movement of ions present in the solid electrolyte layer.

The ion controllable transistor-based neuromorphic synaptic device may analogically update the channel conductance by movement of ions present in the solid electrolyte layer, using a characteristic of the solid electrolyte layer in which ions are linearly and analogically distributed.

The ion controllable transistor-based neuromorphic synaptic device may analogically express a synaptic weight by analogically updating the channel conductance.

The solid electrolyte layer may include at least one of a sulfide-based material with high ionic conductivity and present in a solid state [Li10GeP2S12, Li9.54Si1.74P1.44S11.7Cl0.3, argyrodite, lithium phosphorus sulfide (LPS), LPS+LiCl], an oxide-based material [perovskite, NASICON (Na1+xZr2SixP3−xO12, 0<x<3), LISICON (Li2+2xZn1−xGeO4), LiPON (LixPOyNz), garnet], and an ion conductive polymer [polyethylene oxide (PEO), polyethylene glycol (PEG), polyethylene glycol dimethacrylate (PEGDMA), polytetrafluoroethylene (PTFE), polyether ether ketone (PEEK), nafion (C7HF13O5S.C2F4)].

The channel area, the source area, and the drain area may form a semiconductor area in a structure formed in a horizontal direction or a vertical direction.

The channel area may include at least one semiconductor material of silicon (Si), germanium (Ge, SiGe), a group III-V compound, and a 2-D material including carbon nanotube, MoS2, and graphene.

The source area and the drain area may be formed in a form in which impurity ions are implanted into a semiconductor material forming the channel area, formed of a silicide alloy that contains at least one of Al, W, Ti, Co, Ni, Er, and Pt, or formed of at least one metal of Au, Al, Ag, Mg, Ca, Yb, Cs—ITO, Ti, Cr, and Ni.

The interlayer insulating film may include at least one material of silicon oxide (SiO₂), germanium oxide (GeO₂), a solid oxide film, and a low-k dielectric film capable of insulating between the gate area and the channel area, when the ion controllable transistor-based neuromorphic synaptic device updates a synaptic weight update or a transistor operation.

The ion controllable transistor-based neuromorphic synaptic device may further include a sacrificial insulating film formed of at least one of silicon oxide (SiO₂), germanium oxide (GeO₂), a solid oxide film, and a low-k dielectric film, while being provided on the source area and the drain area.

The ion controllable transistor-based neuromorphic synaptic device may be configured as a 3-terminal that includes a terminal of the gate area, a terminal of the source area, and a terminal of the drain area, or a 4-terminal that includes a body terminal with the terminal of the gate area, the terminal of the source area, and the terminal of the drain area.

According to another aspect of an example embodiment, there is provided a gate-first manufacturing method of an ion controllable transistor-based neuromorphic synaptic device, the gate-first manufacturing method including depositing an interlayer insulating film, a solid electrolyte layer, and a gate area on a semiconductor substrate; patterning a portion of the interlayer insulating film, the solid electrolyte layer, and the gate area provided on a channel area that is formed on the semiconductor substrate; forming a source area and a drain area on a portion of the semiconductor substrate exposed as the patterning result, the portion of the semiconductor substrate being present at both sides of the channel area; and depositing a sacrificial insulating film on the source area and the drain area.

According to another aspect of an example embodiment, there is provided a gate-last manufacturing method of an ion controllable transistor-based neuromorphic synaptic device, the gate-last manufacturing method including forming a source area and a drain area on a semiconductor substrate, a dummy gate being provided on a channel area that is formed on the semiconductor substrate; depositing a sacrificial insulating film on the semiconductor substrate; selectively removing the dummy gate; and forming an interlayer insulating film, a solid electrolyte layer, and a gate area in a space in which the dummy gate is removed.

According to another aspect of an example embodiment, there is provided a synaptic array including a plurality of ion controllable transistor-based neuromorphic synaptic devices, wherein each of the plurality of ion controllable transistor-based neuromorphic synaptic devices includes a channel area formed on a semiconductor substrate; a source area and a drain area formed at both sides of the channel area, respectively; an interlayer insulating film provided on the channel area; a gate area formed on the interlayer insulating film; and a solid electrolyte layer inserted between the interlayer insulating film and the gate area.

The synaptic array may be configured to support a parallel operation of updating a synaptic weight through a terminal of the gate area and reading the updated synaptic weight through a terminal of the drain area in each of the plurality of ion controllable transistor-based neuromorphic synaptic devices.

According to another aspect of an example embodiment, there is provided an ion controllable transistor-based neuromorphic synaptic device including a channel area formed on a semiconductor substrate; a source area and a drain area formed at both sides of the channel area, respectively; an interlayer insulating film provided on the channel area; a gate area formed on the interlayer insulating film; and a solid electrolyte layer configured to analogically update channel conductance by movement of ions present in the solid electrolyte layer in response to a voltage pulse being applied to the gate area, based on a characteristic that the ions are linearly and analogically distributed inside the solid electrolyte layer, with being inserted between the interlayer insulating film and the gate area. Here, a synaptic weight is analogically expressed by analogically updating the channel conductance.

According to some example embodiments, it is possible to provide a neuromorphic synaptic device that may secure a stable device characteristic and, at the same time, achieve a large-scale process and integration by using a solid electrolyte layer that analogically updates a channel conductance and a synaptic weight by movement of ions present in the solid electrolyte layer.

In detail, according to some example embodiments, it is possible to provide a neuromorphic synaptic device that may implement a memory operation through a linear movement of cations and anions present in a solid electrolyte layer and may remember a change in channel conductance caused by ion movement as a synaptic weight.

Also, according to some example embodiments, it is possible to provide a neuromorphic synaptic device that may implement STDP, STP, and LTP characteristics like a synapse of a real living organism by adjusting a frequency and a width of a voltage pulse applied to a gate area or by adjusting materials that form a channel area, a solid electrolyte area, the gate area, and a source area.

According to some example embodiments, it is possible to provide a neuromorphic synaptic device that may apply to a spiking neural network as well as a deep neural network.

The example embodiments are not limited to the effects and may be variously modified without departing from the technical spirit and scope.

Further areas of applicability will become apparent from the description provided herein. The description and specific examples in this summary are intended for purposes of illustration only and are not intended to limit the scope of the present disclosure.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a perspective view illustrating an ion controllable transistor-based neuromorphic synaptic device according to an example embodiment;

FIG. 2A is a graph showing a measurement of a drain voltage (I_{D}) over a gate voltage (V_{G}) of an ion controllable transistor-based neuromorphic synaptic device according to an example embodiment;

FIGS. 2B and 2C illustrate an operation of updating channel conductance by movement of ions present in a solid electrolyte layer included in an ion controllable transistor-based neuromorphic synaptic device according to an example embodiment;

FIG. 3 is a graph showing a weight potentiation characteristic and a weight depression characteristic of a solid electrolyte layer included in an ion controllable transistor-based neuromorphic synaptic device according to an example embodiment;

FIG. 4 is a flowchart illustrating a gate-first manufacturing method of an ion controllable transistor-based neuromorphic synaptic device according to an example embodiment;

FIGS. 5A to 5D are X-Z cross-sectional views illustrating a gate-first manufacturing method of an ion controllable transistor-based neuromorphic synaptic device according to an example embodiment;

FIG. 6 is a flowchart illustrating a gate-last manufacturing method of an ion controllable transistor-based neuromorphic synaptic device according to an example embodiment;

FIGS. 7A to 7D are X-Z cross-sectional views illustrating a gate-last manufacturing method of an ion controllable transistor-based neuromorphic synaptic device according to an example embodiment; and

FIG. 8 illustrates a synaptic array configured as an ion controllable transistor-based neuromorphic synaptic device according to an example embodiment.

### DETAILED DESCRIPTION

Aspects and features of the disclosure and methods to achieve the same may become clear with reference to the accompanying drawings and the following example embodiments. The example embodiments, however, may be embodied in various different forms, and should not be construed as being limited to only the illustrated embodiments. Rather, the illustrated embodiments are provided as examples so that this disclosure will be thorough and complete, and are defined by the scope of the claims.

The terms used herein are to describe the example embodiments and not to limit the disclosure. As used herein, the singular forms “a,” “an,” and “the,” are intended to include the plural forms as well, unless the context clearly indicates otherwise. It will be further understood that the terms “comprises” and/or “comprising,” when used in this specification, specify the presence of stated features, steps, operations, and/or components, but do not preclude the presence or addition of one or more other features, steps, operations, elements, components, and/or groups, thereof.

Unless otherwise defined, all terms (including technical and scientific terms) used herein have the same meaning as commonly understood by one of ordinary skill in the art to which example embodiments belong. Terms, such as those defined in commonly used dictionaries, should be interpreted as having a meaning that is consistent with their meaning in the context of the relevant art and/or this disclosure, and should not be interpreted in an idealized or overly formal sense unless expressly so defined herein.

Hereinafter, the example embodiments will be described in more detail with reference to the accompanying drawings. Like reference numerals refer to like elements throughout.

Also, terminologies used herein are to appropriately express example embodiments and may vary according to the intent of a user or an operator, or a custom in the field to which the disclosure pertains. Accordingly, the terminologies should be defined based on the overall contents of the present specification.

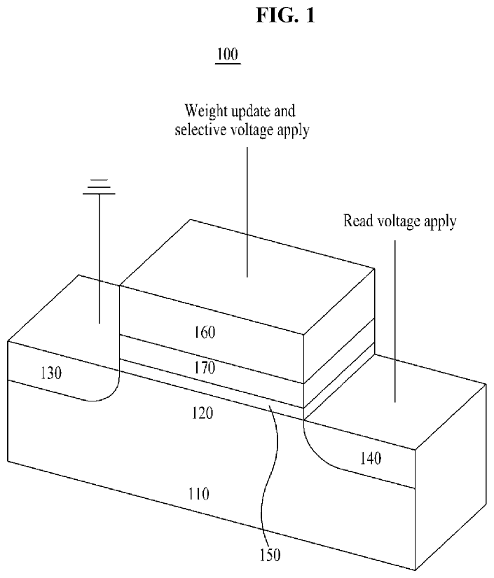

FIG. 1 is a perspective view illustrating an ion controllable transistor-based neuromorphic synaptic device according to an example embodiment. Hereinafter, although it is described that an ion controllable transistor-based neuromorphic synaptic device 100 is in a structure formed in a horizontal direction for clarity of description, the ion controllable transistor-based neuromorphic synaptic device 100 may have a structure formed in a vertical direction in terms of integration.

Referring to FIG. 1, the ion controllable transistor-based neuromorphic synaptic device 100 according to an example embodiment may include a semiconductor substrate 110, a channel area 120, a source area 130, and a drain area 140, an interlayer insulating film 150, a gate area 160, and a solid electrolyte layer 170.

For the semiconductor substrate 110, a single wafer may be selected from among a silicon wafer, a strained silicon wafer, a germanium wafer, a strained germanium wafer, and a silicon germanium wafer and then be used.

The channel area 120 may be formed on the semiconductor substrate 110 using at least one semiconductor material of silicon (Si), germanium (Ge, SiGe), a group III-V compound, and a 2-D material (carbon nanotube (CNT), MoS2, graphene, etc.).

The source area 130 and the drain area 140 may be formed at both sides of the channel area 120, respectively, and more particularly, may be formed in a form in which impurity ions (N-type impurities such as arsenic (As), phosphorous (P), etc., or P-type impurities such as boron (B)) are implanted into a semiconductor material that forms the channel area 120, may be formed of a silicide alloy that contains at least one of Al, W, Ti, Co, Ni, Er, and Pt, or may be formed of at least one metal of Au, Al, Ag, Mg, Ca, Yb, Cs—ITO, Ti, Cr, and Ni. For example, when a semiconductor area that is the semiconductor substrate 110 including the channel area 120, the source area 130, and the drain area 140 is to be formed through impurity ion implantation, the source area 130 and the drain area 140 may be formed by providing a silicide alloy such as Al, W, Ti, Co, Ni, Er, and Pt. As another example, when the semiconductor area is to be formed using a 2-D material, the source area 130 and the drain area 140 may be formed by providing at least one metal of Au, Al, Ag, Mg, Ca, Yb, Cs—ITO, Ti, Cr, and Ni.

Here, the source area 130 and the drain area 140 need to have the same impurity ion type, and an impurity ion type of the channel area 120 may differ from the impurity ion type of each of the source area 130 and the drain area 140. Here, in a junctionless structure, the impurity ion type of the channel area 120 may be identical to the impurity ion type of each of the source area 130 and the drain area 140.

The channel area 120, the source area 130, and the drain area 140 may constitute the semiconductor area, may be formed using at least one of a silicon wafer, a germanium wafer, a group III-V compound wafer, and a 2-D material (CNT, MoS2, etc.).

The semiconductor area may be formed as an N+ type/P type/N+ type (source area 130/channel area 120/drain area 140) or a P+ type/N type/P+ type (source area 130/channel area 120/drain area 140) through impurity ion implantation. For example, the semiconductor area may be formed through an ion implantation, an epitaxial growth, or a selective epitaxial growth on the semiconductor substrate 110. When the epitaxial growth is used, the semiconductor area may be formed of at least one of silicon, strained silicon, silicon germanium, and silicon carbide.

Therefore, the semiconductor area provided in order of source area 130/channel area 120/drain area 140 may have an N+ type/P type/N+ type or a P+ type/N type/P+ type in the case of a junction structure or may have an N+ type/N+ type/N+ type in the case of a junctionless structure.

The interlayer insulating film 150 may be provided on the channel area 120, and may be formed of at least one material of silicon oxide (SiO₂), germanium oxide (GeO₂), a solid oxide film, and a low-k dielectric film that may insulate between the gate area 160 and the channel area 120, when the ion controllable transistor-based neuromorphic synaptic device 100 performs a synaptic weight update or a transistor operation.

The gate area 160 may be formed on the interlayer insulating film 150, and the solid electrolyte layer 170 may be inserted between the gate area 160 and the interlayer insulating film 150.

The solid electrolyte layer 170 may be formed at least one of a sulfide-based material with high ionic conductivity and present in a solid state [Li10GeP2S12, Li9.54Si1.74P1.44S11.7Cl0.3, argyrodite, lithium phosphorus sulfide (LPS), LPS+LiCl], an oxide-based material [perovskite, NASICON (Na1+xZr2SixP3−xO12, 0<x<3), LISICON (Li2+2xZn1−xGeO4), LiPON (LixPOyNz), garnet], and an ion conductive polymer [polyethylene oxide (PEO), polyethylene glycol (PEG), polyethylene glycol dimethacrylate (PEGDMA), polytetrafluoroethylene (PTFE), polyether ether ketone (PEEK), nafion (C7HF13O5S.C2F4)].

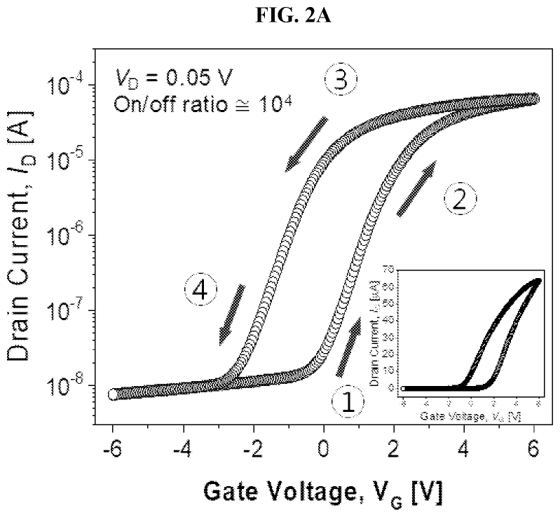

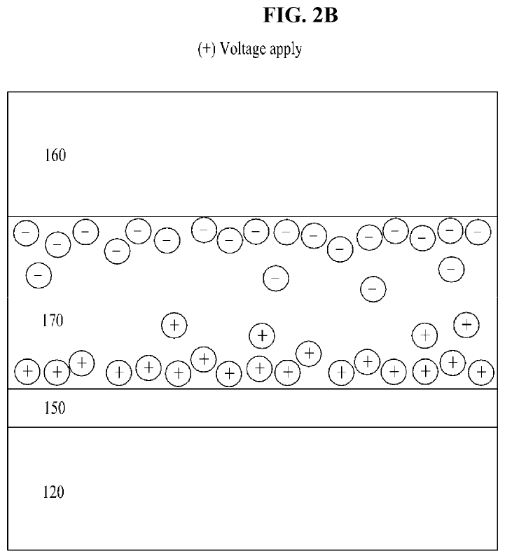

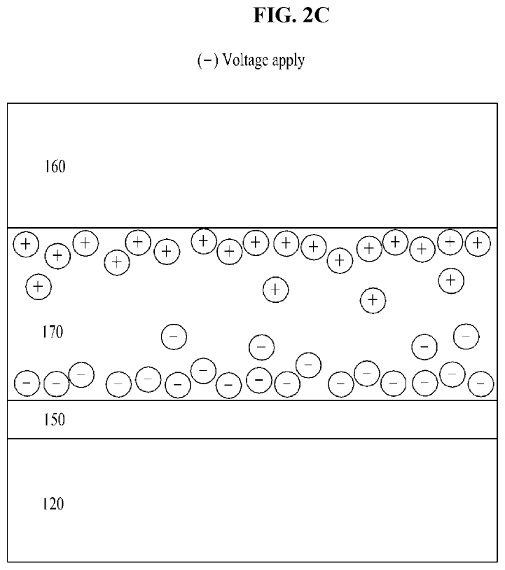

Here, the solid electrolyte layer 170 may be used to change a channel conductance of the ion controllable transistor-based neuromorphic synaptic device 100. Hereinafter, the channel conductance represents conductivity of the channel area 120. That is, the ion controllable transistor-based neuromorphic synaptic device 100 including the solid electrolyte layer 170 may operate based on an operating principle of a field effective transistor (FET) in which current flows through the channel area 120 as a voltage greater than or equal to a threshold voltage applies to the gate area 160 and a specific voltage applies to the drain area 140. Further description related thereto is made below with reference to FIGS. 2A to 2C.

Also, the ion controllable transistor-based neuromorphic synaptic device 100 may further include a sacrificial insulating film 180 provided on the source area 130 and the drain area 140 and formed of at least one material of silicon oxide (SiO₂), germanium oxide (GeO₂), a solid oxide film, and a low-k dielectric film.

FIG. 2A is a graph showing a measurement of a drain voltage I_{D} over a gate voltage V_{G} of an ion controllable transistor-based neuromorphic synaptic device according to an example embodiment, and FIGS. 2B and 2C illustrate an operation of updating channel conductance by movement of ions present in a solid electrolyte layer included in an ion controllable transistor-based neuromorphic synaptic device according to an example embodiment.

Referring to FIGS. 2A to 2C, the ion controllable transistor-based neuromorphic synaptic device 100 may change channel conductance with charge caused by movement of ions inside the solid electrolyte layer 170 that inserts into the gate area 160. Therefore, referring to the graph of FIG. 2A, the drain current I_{D} according to the gate voltage V_{G} may have a hysteresis curve in a counterclockwise direction (\textcircled{1}→\textcircled{2}→\textcircled{3}→\textcircled{4}).

For example, referring to FIG. 2B, when a positive voltage pulse is applied to the gate area 160, cations present in the solid electrolyte layer 170 move closer to the channel area 120 or anions move closer to the gate area 160. Alternatively, at the same time at which the cations move closer to the channel area 120, the anions move closer to the gate area 160. In this manner, potential near the channel area 120 increases. Accordingly, inversion of a semiconductor channel may be facilitated, which may lead to decreasing a threshold voltage and increase the channel conductance.

As another example, referring to FIG. 2C, when a negative voltage pulse is applied to the gate area 160, anions present in the solid electrolyte area 170 move closer to the channel area 120 or cations move closer to the gate area 160. Alternatively, at the same time at which the anions move closer to the channel area 120, the cations move closer to the gate area 160. In this manner, potential near the channel area 120 decreases. Accordingly, inversion of the semiconductor channel becomes difficult, which may lead to increasing the threshold voltage and decreasing the channel conductance.

The channel conductance changed and updated with charge caused by movement of ions in the solid electrolyte layer 170 may represent a synaptic weight of the ion controllable transistor-based neuromorphic synaptic device 100. That is, the ion controllable transistor-based neuromorphic synaptic device 100 may represent potentiation or depression of the synaptic weight by updating the channel conductance based on movement of ions inside the solid electrolyte layer 170.

For example, as described above with reference to FIGS. 2B and 2C, the ion controllable transistor-based neuromorphic synaptic device 100 may increase or decrease the synaptic weight that is the channel conductance. In detail, for example, referring to FIG. 2B, the ion controllable transistor-based neuromorphic synaptic device 100 may apply the positive voltage pulse to the gate area 160 to make the cations present in the solid electrolyte layer 170 move closer to the channel area 120 or to make the anions move closer to the gate area 160, thereby increasing the potential near the channel area 120 and increasing the synaptic weight represented as the channel conductance. As another example, referring to FIG. 2C, the ion controllable transistor-based neuromorphic synaptic device 100 may apply the negative voltage pulse to the gate area 160 to make the anions present in the solid electrolyte layer 170 move closer to the channel area 120 or to make the cations move closer to the gate area 160, thereby decreasing the potential near the channel area 120 and decreasing the synaptic weight represented as the channel conductance.

As described above, in the ion controllable transistor-based neuromorphic synaptic device 100, a memory operation may be implemented with movement of cations and anions present in the solid electrolyte layer 170 and the synaptic device characteristic in neuromorphic computing may be implemented by memorizing, as the synaptic weight, the change in the channel conductance caused by movements of ions.

Although it is described that the ion controllable transistor-based neuromorphic synaptic device 100 implements the synaptic device characteristic of representing the synaptic weight with the change in the channel conductance, it is provided as an example only. Since it is possible to implement spike timing dependent plasticity (STDP), short term plasticity (STP), and long term plasticity (LTP) characteristics like a synapse of a real living organism by adjusting a frequency and a width of a voltage pulse applied to the gate area 160 or by adjusting materials of the channel area 120, the solid electrolyte layer 170, and the gate area 160, it is possible to apply to a spiking neural network as well as a deep neural network.

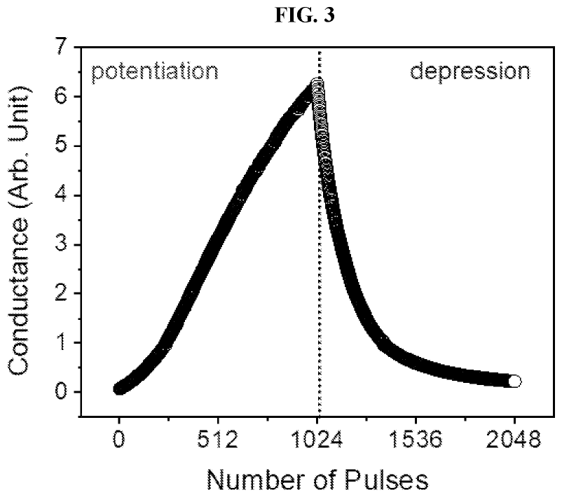

In particular, the ion controllable transistor-based neuromorphic synaptic device 100 may linearly and analogically update the synaptic weight that is the channel conductance. Further description related thereto is made with reference to FIG. 3.

FIG. 3 is a graph showing a weight potentiation characteristic and a weight depression characteristic of a solid electrolyte layer included in an ion controllable transistor-based neuromorphic synaptic device according to an example embodiment.

Referring to the graph of FIG. 3, the ion controllable transistor-based neuromorphic synaptic device 100 may have a large number of synaptic weight stages in a linear and analog manner through synaptic weight potentiation and depression stages. This is due to a characteristic that ions inside the solid electrolyte layer 170 are linearly and analogically distributed. Using such characteristic of the solid electrolyte layer 170, the ion controllable transistor-based neuromorphic synaptic device 100 may linearly and analogically represent the synaptic weight by linearly and analogically updating the channel conductance by movement of ions present in the solid electrolyte layer 170 in response to a voltage pulse being applied to the gate area 160.

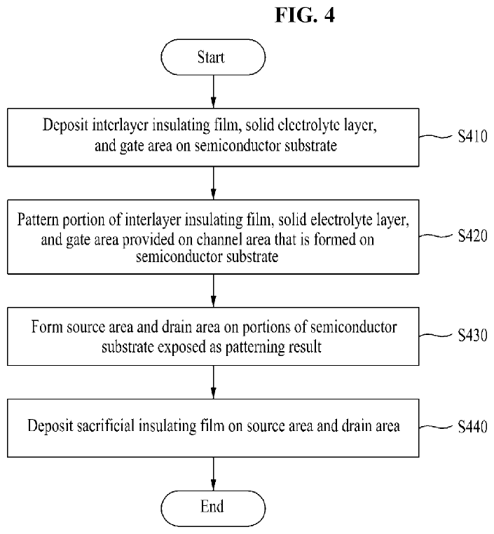

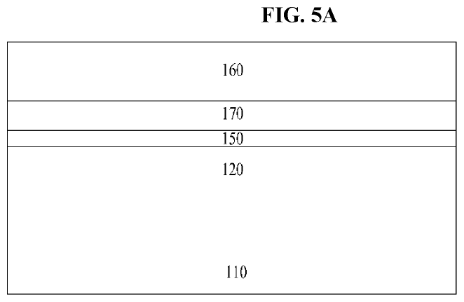

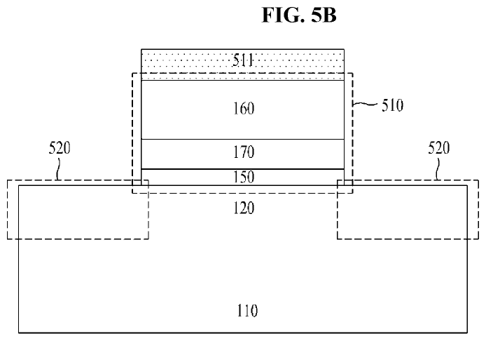

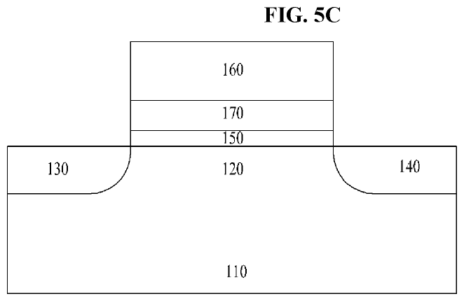

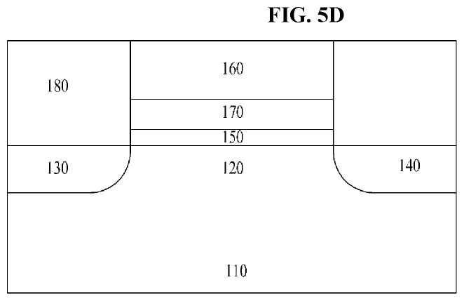

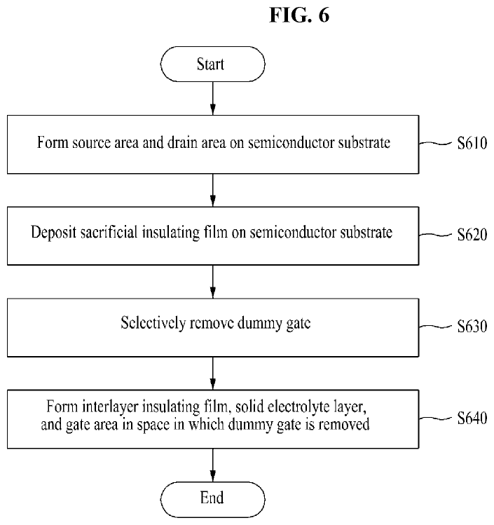

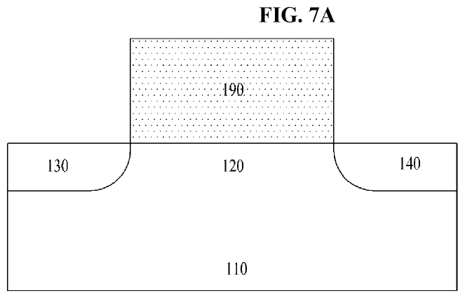

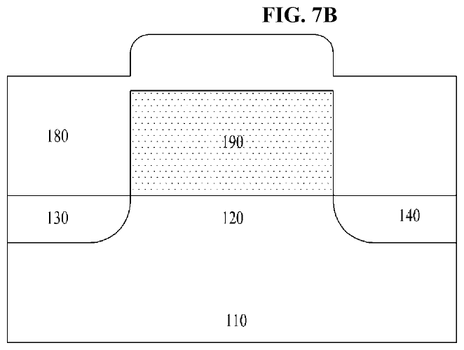

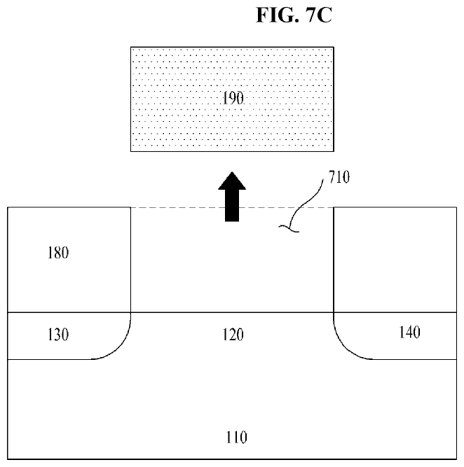

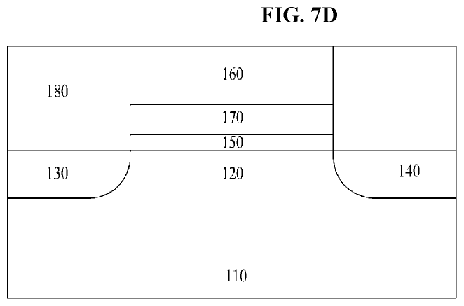

The aforementioned ion controllable transistor-based neuromorphic synaptic device 100 may secure a stable device characteristic and, at the same time, achieve a large-scale process and integration by using the solid electrolyte layer 170 that analogically updates the channel conductance and the synaptic weight by movement of ions in the solid electrolyte layer 170. A manufacturing method of the aforementioned ion controllable transistor-based neuromorphic synaptic device 100 may selectively use one of a gate-first process of forming the gate area 160 first and a gate-last process of forming the gate area 160 last. A gate-first manufacturing method of the ion controllable transistor-based neuromorphic synaptic device 100 using the gate-first process is described with reference to FIG. 4 and FIGS. 5A to 5D, and a gate-last manufacturing method of the ion controllable transistor-based neuromorphic synaptic device 100 using the gate-last process is described with reference to FIG. 6 and FIGS. 7A to 7D.

Also, the aforementioned ion controllable transistor-based neuromorphic synaptic device 100 may be implemented as a 3-terminal device that includes a terminal of the gate area 160, a terminal of the source area 130, and a terminal of the drain area 140. However, it is provided as an example only. Without being limited thereto, the ion controllable transistor-based neuromorphic synaptic device 100 may be implemented as a 4-terminal device that also includes a body terminal with the terminal of the gate area 160, the terminal of the source area 130, and the terminal of the drain area 140.

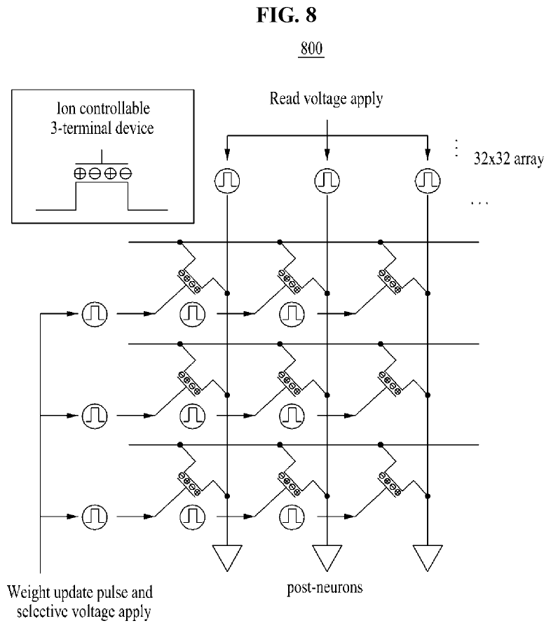

Also, a plurality of ion controllable transistor-based neuromorphic synaptic devices 100 may be provided to form a single synaptic array. Description related thereto is made with reference to FIG. 8.

FIG. 4 is a flowchart illustrating a gate-first manufacturing method of an ion controllable transistor-based neuromorphic synaptic device according to an example embodiment, and FIGS. 5A to 5D are X-Z cross-sectional views illustrating a gate-first manufacturing method of an ion controllable transistor-based neuromorphic synaptic device according to an example embodiment. Here, the ion controllable transistor-based neuromorphic synaptic device 100 manufactured through the following gate-first manufacturing method of the ion controllable transistor-based neuromorphic synaptic device 100 may have the structure and the characteristics described above with reference to FIGS. 1 to 3, and an entity that performs the gate-first manufacturing method of the ion controllable transistor-based neuromorphic synaptic device 100 may be a manufacturing system that is automated and mechanized.

Referring to FIG. 4 and FIGS. 5A to 5D, in operation S410, the manufacturing system may sequentially deposit the interlayer insulating film 150, the solid electrolyte layer 170, and the gate area 160 on the semiconductor substrate 110 as illustrated in FIG. 5A. In particular, the manufacturing system may form the solid electrolyte layer 170 using at least one of a sulfide-based material with a high ionic conductivity and present in a solid state [Li10GeP2S12, Li9.54Si1.74P1.44S11.7Cl0.3, argyrodite, lithium phosphorus sulfide (LPS), LPS+LiC1], an oxide-based material [perovskite, NASICON (Na1+xZr2SixP3−xO12, 0<x<3), LISICON (Li2+2xZn1−xGeO4), LiPON (LixPOyNz), garnet], and an ion conductive polymer [polyethylene oxide (PEO), polyethylene glycol (PEG), polyethylene glycol dimethacrylate (PEGDMA), polytetrafluoroethylene (PTFE), polyether ether ketone (PTFE), nafion (C7HF13O5S.C2F4)], such that the manufactured ion controllable transistor-based neuromorphic synaptic device 100 may linearly and analogically update a channel conductance using a characteristic of the solid electrolyte layer 170 in which ions are linearly and analogically distributed.

Here, the channel area 120 may be formed in an upper area of the semiconductor substrate 100.

In operation S420, the manufacturing system may pattern a portion 510 of the interlayer insulating film 150, the solid electrolyte layer 170, and the gate area 160 provided on the channel area 120 that is formed on the semiconductor substrate 110 as illustrated in FIG. 5B. For example, by providing a photoresistance (PR) 511 on the portion 510 of the interlayer insulating film 150, the solid electrolyte layer 170, and the gate area 160 provided on the channel area 120, the manufacturing system may perform a patterning of leaving the portion 510 of the interlayer insulating film 150, the solid electrolyte layer 170, and the gate area 160 provided on the channel area 120.

The PR 511 used in operation S420 may be removed before operation S430.

In operation S430, the manufacturing system may form the source area 130 and the drain area 140 on portions 520 of the semiconductor substrate 110 exposed as a patterning result as illustrated in FIGS. 5B and 5C. Here, the portions 520 of the semiconductor substrate 110 are present at both sides of the channel area 120, respectively. For example, the manufacturing system may form the source area 130 and the drain area 140 on the portions 520 of the semiconductor substrate 110, respectively, exposed as the patterning result through one of an impurity ion implantation, a silicide alloy deposition including at least one of Al, W, Ti, Co, Ni, Er, and Pt, and a metal deposition including at least one of Au, Al, Ag, Mg, Ca, Yb, Cs—ITO, Ti, Cr, and Ni. Here, when the source area 130 and the drain area 140 are formed using the silicide alloy deposition or the metal deposition, one of an inkjet printing scheme, a printing process such as spraying, a chemical vapor deposition scheme, an evaporation scheme, and a sputtering scheme may be employed.

In operation S440, the manufacturing system may deposit the sacrificial insulating film 180 on the source area 130 and the drain area 140 as illustrated in FIG. 5D. Also, in operation S440, the manufacturing system may form a contact (not shown) through a back-end of line (BEOL).

FIG. 6 is a flowchart illustrating a gate-last manufacturing method of an ion controllable transistor-based neuromorphic synaptic device according to an example embodiment, and FIGS. 7A to 7D are X-Z cross-sectional views illustrating a gate-last manufacturing method of an ion controllable transistor-based neuromorphic synaptic device according to an example embodiment. Here, the ion controllable transistor-based neuromorphic synaptic device 100 manufactured through the following gate-last manufacturing method of the ion controllable transistor-based neuromorphic synaptic device 100 may have the structure and the characteristics described above with reference to FIGS. 1 to 3, and an entity that performs the gate-last manufacturing method of the ion controllable transistor-based neuromorphic synaptic device 100 may be a manufacturing system that is automated and mechanized.

Referring to FIG. 6 and FIGS. 7A to 7D, in operation S610, the manufacturing system may form the source area 130 and the drain area 140 on the semiconductor substrate 110 as illustrated in FIG. 7A. Here, the channel area 120 may be formed on the semiconductor substrate 110 and a dummy gate 190 may be provided on the channel area 120.

For example, the manufacturing system may form the source area 130 and the drain area 140 on areas provided at both sides of the channel area 120 on the semiconductor substrate 110, respectively, through one of an impurity ion implantation, a silicide alloy deposition including at least one of Al, W, Ti, Co, Ni, Er, and Pt, and a metal deposition including at least one of Au, Al, Ag, Mg, Ca, Yb, Cs—ITO, Ti, Cr, and Ni. Here, when the source area 130 and the drain area 140 are formed using the silicide alloy deposition or the metal deposition, one of an inkjet printing scheme, a printing process such as spraying, a chemical vapor deposition scheme, an evaporation scheme, and a sputtering scheme may be employed.

In operation S620, the manufacturing system may deposit the sacrificial insulating film 180 on the semiconductor substrate 110 as illustrated in FIG. 7B.

In operation S630, the manufacturing system may selectively remove the dummy gate 190 as illustrated in FIGS. 7B and 7C. For example, the manufacturing system may chemically polish and smoothen the sacrificial insulating film 180 until the dummy gate 190 is exposed and then may selectively remove only the dummy gate 190.

In operation S640, the manufacturing system may form the interlayer insulating film 150, the solid electrolyte layer 170, and the gate area 160 in a space 710 in which the dummy gate 190 is removed as illustrated in FIGS. 7C and 7D. In particular, the manufacturing system may form the solid electrolyte layer 170 using at least one of a sulfide-based material with a high ionic conductivity and present in a solid state [Li10GeP2S12, Li9.54Si1.74P1.44S11.7Cl0.3, argyrodite, lithium phosphorus sulfide (LPS), LPS+LiCl], an oxide-based material [perovskite, NASICON (Na1+xZr2SixP3−xO12, 0<x<3), LISICON (Li2+2xZn1−xGeO4), LiPON (LixPOyNz), garnet], and an ion conductive polymer [polyethylene oxide (PEO), polyethylene glycol (PEG), polyethylene glycol dimethacrylate (PEGDMA), polytetrafluoroethylene (PTFE), polyether ether ketone (PEEK), nafion (C7HF13O5S.C2F4)], such that the manufactured ion controllable transistor-based neuromorphic synaptic device 100 may linearly and analogically update a channel conductance using a characteristic of the solid electrolyte layer 170 in which ions are linearly and analogically distributed.

Also, in operation 640, the manufacturing system may form a contact (not shown) through a back-end of line (BEOL).

FIG. 8 illustrates a synaptic array configured as an ion controllable transistor-based neuromorphic synaptic device according to an example embodiment.

Referring to FIG. 8, a synaptic array 800 may be implemented by providing a plurality of ion controllable transistor-based neuromorphic synaptic devices 100 described above with reference to FIGS. 1 to 3. Therefore, the synaptic array 800 may include the plurality of ion controllable transistor-based neuromorphic synaptic devices 100. As described above, each of the plurality of ion controllable transistor-based neuromorphic synaptic devices 100 may include the channel area 120 formed on the semiconductor substrate 110, the source area 130 and the drain area 140 formed at both sides of the channel area 120, respectively, the interlayer insulating film 150 formed on the channel area 120, the gate area 160 formed on the interlayer insulating film 150, and the solid electrolyte layer 170 inserted between the interlayer insulating film 150 and the gate area 160.

The synaptic array 800 has a structure in which a terminal of the gate area 160 and a terminal of the drain area 140 are separate in each of the plurality of ion controllable transistor-based neuromorphic synaptic devices 100 and thus, may support a parallel operation of updating a synaptic weight through the terminal of the gate area 160 and reading the synaptic weight through the terminal of the drain area 140.

While this disclosure includes specific example embodiments, it will be apparent to one of ordinary skill in the art that various alterations and modifications in form and details may be made in these example embodiments without departing from the spirit and scope of the claims and their equivalents. For example, suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An ion controllable transistor-based neuromorphic synaptic device comprising:
a channel area formed on a semiconductor substrate;
a source area and a drain area formed at both sides of the channel area, respectively;
an interlayer insulating film provided on the channel area;
a gate area formed on the interlayer insulating film; and
a solid electrolyte layer inserted between the interlayer insulating film and the gate area.

2. The ion controllable transistor-based neuromorphic synaptic device of claim 1, wherein, in response to a voltage pulse being applied to the gate area, the ion controllable transistor-based neuromorphic synaptic device analogically updates channel conductance by movement of ions present in the solid electrolyte layer.

3. The ion controllable transistor-based neuromorphic synaptic device of claim 2, wherein the ion controllable transistor-based neuromorphic synaptic device analogically updates the channel conductance by movement of ions present in the solid electrolyte layer, using a characteristic of the solid electrolyte layer in which ions are linearly and analogically distributed.

4. The ion controllable transistor-based neuromorphic synaptic device of claim 2, wherein the ion controllable transistor-based neuromorphic synaptic device analogically expresses a synaptic weight by analogically updating the channel conductance.

5. The ion controllable transistor-based neuromorphic synaptic device of claim 1, wherein the solid electrolyte layer comprises at least one of a sulfide-based material with high ionic conductivity and present in a solid state [Li10GeP2S12, Li9.54Si1.74P1.44S11.7Cl0.3, argyrodite, lithium phosphorus sulfide (LPS), LPS+LiCl], an oxide-based material [perovskite, NASICON (Na1+xZr2SixP3−xO12, 0<x<3), LISICON (Li2+2xZn1−xGeO4), LiPON (LixPOyNz), garnet], and an ion conductive polymer [polyethylene oxide (PEO), polyethylene glycol (PEG), polyethylene glycol dimethacrylate (PEGDMA), polytetrafluoroethylene (PTFE), polyether ether ketone (PEEK), nafion (C7HF13O5S.C2F4)].

6. The ion controllable transistor-based neuromorphic synaptic device of claim 1, wherein the channel area, the source area, and the drain area form a semiconductor area in a structure formed in a horizontal direction or a vertical direction.

7. The ion controllable transistor-based neuromorphic synaptic device of claim 1, wherein the channel area comprises at least one semiconductor material of silicon (Si), germanium (Ge, SiGe), a group III-V compound, and a 2-D material including carbon nanotube, MoS2, and graphene.

8. The ion controllable transistor-based neuromorphic synaptic device of claim 1, wherein the source area and the drain area are formed in a form in which impurity ions are implanted into a semiconductor material forming the channel area, formed of a silicide alloy that contains at least one of Al, W, Ti, Co, Ni, Er, and Pt, or formed of at least one metal of Au, Al, Ag, Mg, Ca, Yb, Cs—ITO, Ti, Cr, and Ni.

9. The ion controllable transistor-based neuromorphic synaptic device of claim 1, wherein the interlayer insulating film comprises at least one material of silicon oxide (SiO₂), germanium oxide (GeO₂), a solid oxide film, and a low-k dielectric film capable of insulating between the gate area and the channel area, when the ion controllable transistor-based neuromorphic synaptic device updates a synaptic weight update or a transistor operation.

10. The ion controllable transistor-based neuromorphic synaptic device of claim 1, further comprising:
a sacrificial insulating film formed of at least one of silicon oxide (SiO₂), germanium oxide (GeO₂), a solid oxide film, and a low-k dielectric film, while being provided on the source area and the drain area.

11. The ion controllable transistor-based neuromorphic synaptic device of claim 1, wherein the ion controllable transistor-based neuromorphic synaptic device is configured as a 3-terminal that includes a terminal of the gate area, a terminal of the source area, and a terminal of the drain area, or a 4-terminal that includes a body terminal with the terminal of the gate area, the terminal of the source area, and the terminal of the drain area.

12. A gate-first manufacturing method of an ion controllable transistor-based neuromorphic synaptic device, the gate-first manufacturing method comprising:
depositing an interlayer insulating film, a solid electrolyte layer, and a gate area on a semiconductor substrate;
patterning a portion of the interlayer insulating film, the solid electrolyte layer, and the gate area provided on a channel area that is formed on the semiconductor substrate;
forming a source area and a drain area on a portion of the semiconductor substrate exposed as the patterning result, the portion of the semiconductor substrate being present at both sides of the channel area; and
depositing a sacrificial insulating film on the source area and the drain area.

13. A gate-last manufacturing method of an ion controllable transistor-based neuromorphic synaptic device, the gate-last manufacturing method comprising:
forming a source area and a drain area on a semiconductor substrate, a dummy gate being provided on a channel area that is formed on the semiconductor substrate;
depositing a sacrificial insulating film on the semiconductor substrate;
selectively removing the dummy gate; and
forming an interlayer insulating film, a solid electrolyte layer, and a gate area in a space in which the dummy gate is removed.

14. A synaptic array comprising a plurality of ion controllable transistor-based neuromorphic synaptic devices, wherein each of the plurality of ion controllable transistor-based neuromorphic synaptic devices comprises:
a channel area formed on a semiconductor substrate;
a source area and a drain area formed at both sides of the channel area, respectively;
an interlayer insulating film provided on the channel area;
a gate area formed on the interlayer insulating film; and
a solid electrolyte layer inserted between the interlayer insulating film and the gate area.

15. The synaptic array of claim 14, wherein the synaptic array is configured to support a parallel operation of updating a synaptic weight through a terminal of the gate area and reading the updated synaptic weight through a terminal of the drain area in each of the plurality of ion controllable transistor-based neuromorphic synaptic devices.
